(19) United States
(12) Patent Application Publication
(10) Pub. No.: US 2025/0008733 A1
(43) Pub. Date: Jan. 2, 2025

(54) SEMICONDUCTOR DEVICE AND METHOD OF MANUFACTURING THE SAME

(71) Applicant: SK hynix Inc., Icheon-si Gyeonggi-do (KR)

(72) Inventors: Seok Min CHOI, Icheon-si Gyeonggi-do (KR); Jung Shik JANG, Icheon-si Gyeonggi-do (KR); Rho Gyu KWAK, Icheon-si Gyeonggi-do (KR); Jeong Hwan KIM, Icheon-si Gyeonggi-do (KR); In Su PARK, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 18/523,112

(22) Filed: Nov. 29, 2023

(30) Foreign Application Priority Data
Jun. 27, 2023 (KR) 10-2023-0082574

(51) Int. Cl. H10B 43/27; H10B 43/10

(52) U.S. Cl. CPC H10B 43/27; H10B 43/10

(57) ABSTRACT

A semiconductor device, and a method of manufacturing the same, includes a gate stack including a plurality of conductive lines extending in a first horizontal direction, a first slit and a second slit passing through the gate stack in a vertical direction and extending in the first horizontal direction, and a plurality of cell plugs extending in the vertical direction orthogonal to the first horizontal direction in the gate stack between the first slit and the second slit. Each of the first slit and the second slit includes a first portion extending in a diagonal direction between the first horizontal direction and a second horizontal direction orthogonal to the first horizontal direction, and a second portion extending in the first horizontal direction.

### CROSS-REFERENCE TO RELATED APPLICATION

The present application claims priority under 35 U.S.C. § 119(a) to Korean patent application number 10-2023-0082574 filed on Jun. 27, 2023, in the Korean Intellectual Property Office, the entire disclosure of which is incorporated by reference herein.

### BACKGROUND

### 1. Technical Field

The present disclosure relates to an electronic device, and more particularly, to a semiconductor device and a method of manufacturing the same.

### 2. Related Art

A nonvolatile memory element is a memory element in which stored data is maintained even though supplied power is cut off. Recently, as improvement of an integration degree of a two-dimensional nonvolatile memory element that forms a memory cell in a single layer on a substrate has reached a limit, a three-dimensional nonvolatile memory element that vertically stacks memory cells on a substrate has been proposed.

The three-dimensional nonvolatile memory element includes interlayer insulating layers and gate electrodes which are alternately stacked, and channel structures passing through the interlayer insulating layers and the gate electrodes, and memory cells are stacked along the channel structures. Various structures and manufacturing methods have been developed to improve reliability of the nonvolatile memory element having such a three-dimensional structure.

### SUMMARY

According to an embodiment of the present disclosure, a semiconductor device includes: a gate stack including a plurality of conductive lines extending in a first horizontal direction; a first slit and a second slit passing through the gate stack in a vertical direction and extending in the first horizontal direction; and a plurality of cell plugs extending in the vertical direction orthogonal to the first horizontal direction in the gate stack between the first slit and the second slit. Each of the first slit and the second slit includes a first portion extending in a diagonal direction between the first horizontal direction and a second horizontal direction, and a second portion extending in the first horizontal direction.

According to an embodiment of the present disclosure, a semiconductor device includes: a gate stack including a plurality of conductive lines extending in a first horizontal direction; a first slit and a second slit disposed at both ends of the gate stack and extending parallel to the first horizontal direction; a plurality of cell plugs extending in a vertical direction orthogonal to the first horizontal direction in the gate stack between the first slit and the second slit; and at least one third slit extending in the first horizontal direction by passing through an upper portion of the gate stack between the first slit and the second slit by a predetermined thickness, and extending in parallel with the first slit and the second slit. The first slit and the second slit have a wave pattern or a zigzag pattern along the first horizontal direction.

According to an embodiment of the present disclosure, a method of manufacturing a semiconductor device includes: forming a plurality of preliminary channel holes and a plurality of preliminary slit holes passing through a stack in which a plurality of interlayer insulating layers and a plurality of sacrificial layers are alternately stacked; filling the plurality of preliminary channel holes and the plurality of preliminary slit holes with a gap fill pattern; forming a first insulating layer on the stack, and forming channel holes exposing the gap fill patterns formed inside the plurality of preliminary channel holes, by selectively etching the first insulating layer; extending the channel holes into the stack by removing the gap fill patterns exposed through the channel holes; forming cell plugs inside the channel holes; forming a second insulating layer on the cell plugs and the first insulating layer, and forming slit holes exposing the gap fill patterns formed inside the plurality of preliminary slit holes, by selectively etching the second insulating layer and the first insulating layer; forming a recess area by removing the gap fill patterns exposed through the slit holes and etching the plurality of interlayer insulating layers exposed through a sidewall of the slit holes by a predetermined thickness; forming a plurality of conductive layers in a space where the plurality of sacrificial layers are removed, after removing the plurality of sacrificial layers exposed through the slit holes; forming a trench in which the slit holes are connected to each other by removing the plurality of conductive layers remaining inside the slit holes; and forming a slit by filling the trench with an insulating material. The recess areas of adjacent slit holes are in contact with each other.

### BRIEF DESCRIPTION OF THE DRAWINGS

FIGS. 1A and 1B are block diagrams illustrating semiconductor devices according to embodiments of the present disclosure.

FIG. 2 is a cross-sectional view illustrating a peripheral circuit structure.

FIGS. 3A and 3B are plan and cross-sectional views illustrating a semiconductor device according to an embodiment of the present disclosure.

FIGS. 4A to 4K are plan views and cross-sectional views illustrating a method of manufacturing a semiconductor device according to the present disclosure.

FIG. 5 is a plan view illustrating a semiconductor device according to another embodiment of the present disclosure.

FIG. 6 is a plan view illustrating a semiconductor device according to still another embodiment of the present disclosure.

FIG. 7 is a block diagram illustrating a configuration of a memory system according to an embodiment of the present disclosure.

### DETAILED DESCRIPTION

Hereinafter, some embodiments of the present disclosure are described. In the drawings, thicknesses and distances are expressed for convenience of description, and may be exaggerated relative to the actual physical thickness. In describing the present disclosure, known configurations irrespective of the gist of the present disclosure may be omitted. It should be noted that in adding reference numerals to the components of each drawing, the same components have the same number when possible, even though the same components are shown in different drawings.

Throughout the specification, in a case in which a portion is “connected” to another portion, the case includes not only a case in which the portion is “directly connected” to the other portion but also a case in which the portion is “indirectly connected” to the other portion with another element interposed therebetween. Throughout the specification, in a case in which a portion includes a component, the case means that the portion may further include other components without excluding other components unless specifically stated otherwise.

An embodiment of the present disclosure provides a semiconductor device having a stable structure and an improved characteristic, and a method of manufacturing the same. According to an embodiment of the present technology, tensile stress or compressive stress generated in one direction of a memory block may be distributed by extending a slit structure in a zigzag direction.

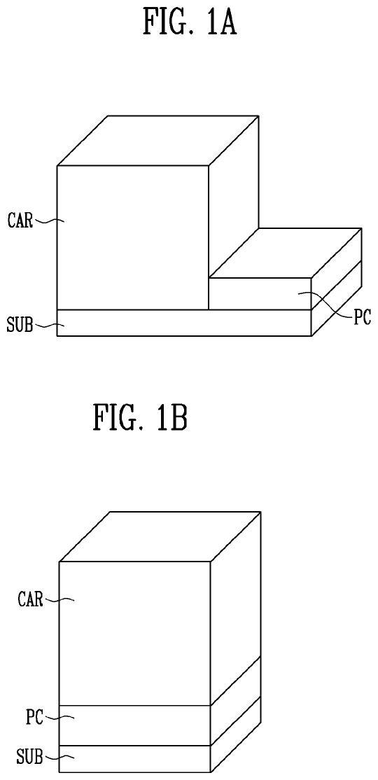

FIGS. 1A and 1B are block diagrams illustrating semiconductor devices according to embodiments of the present disclosure.

Referring to FIGS. 1A and 1B, each of the semiconductor devices according to embodiments of the present disclosure may include a peripheral circuit structure PC and a cell array CAR disposed on a substrate SUB.

The substrate SUB may be a single crystal semiconductor layer. For example, the substrate SUB may be a bulk-silicon substrate, a silicon-on-insulator substrate, a germanium substrate, a germanium-on-insulator substrate, a silicon-germanium substrate, or an epitaxial thin layer formed through a selective epitaxial growth method.

The cell array CAR may include a plurality of memory blocks. Each of the memory blocks may include a plurality of cell strings. Each of the cell strings is electrically connected to a bit line, a source line, word lines, and select lines. Each of the cell strings may include memory cells and select transistors connected in series. Each of the select lines is used as a gate electrode of a select transistor corresponding thereto, and each of the word lines is used as a gate electrode of a memory cell corresponding thereto.

The peripheral circuit structure PC may include an NMOS transistor, PMOS transistors, a resistor, and a capacitor electrically connected to the cell array CAR. The NMOS and PMOS transistors, the resistor, and the capacitor may be used as elements configuring a row decoder, a column decoder, a page buffer, and a control circuit.

As shown in FIG. 1A, the peripheral circuit structure PC may be disposed on a partial region of the substrate SUB, which does not overlap the cell array CAR.

Alternatively, as shown in FIG. 1B, the peripheral circuit structure PC may be disposed between the cell array CAR and the substrate SUB. In this case, because the peripheral circuit structure PC overlaps the cell array CAR, the area of the substrate SUB occupied by the cell array CAR and the peripheral circuit structure PC may be reduced.

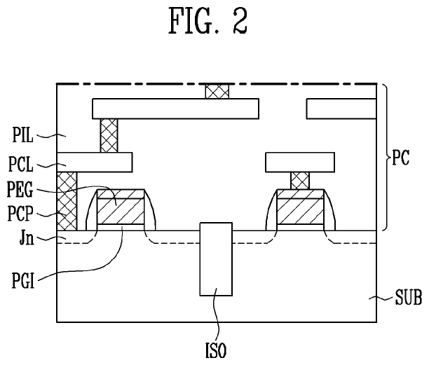

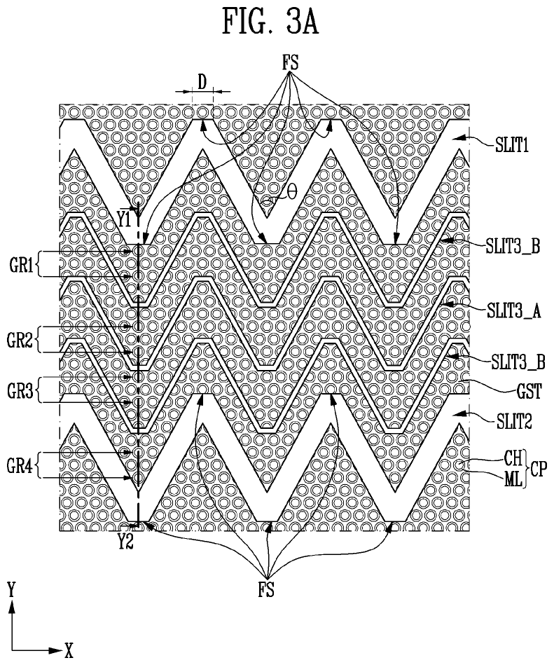

FIG. 2 is a cross-sectional view illustrating a peripheral circuit structure. The peripheral circuit structure PC shown in FIG. 2 may be included in the peripheral circuit structure shown in FIG. 1A or may be included in the peripheral circuit structure shown in FIG. 1B.

Referring to FIG. 2, the peripheral circuit structure PC may include peripheral gate electrodes PEG, a peripheral gate insulating layer PGI, junctions Jn, peripheral circuit lines PCL, peripheral contact plugs PCP, and a peripheral circuit insulating layer PIL.

Each of the peripheral gate electrodes PEG may be used as gate electrodes of the NMOS transistor and a PMOS transistor of the peripheral circuit structure PC. The peripheral gate insulating layer PGI is disposed between each of the peripheral gate electrodes PEG and the substrate SUB.

The junctions Jn are regions defined by implanting an n-type or p-type impurity into an active region of the substrate SUB, are disposed on both sides of each of the peripheral gate electrodes PEG, and are used as a source junction or a drain junction. The active region of the substrate SUB may be partitioned by an isolation layer ISO formed in the substrate SUB. The isolation layer ISO is formed of an insulating material.

The peripheral circuit lines PCL may be electrically connected to a circuit of the peripheral circuit structure PC through the peripheral contact plugs PCP.

The peripheral circuit insulating layer PIL may cover the circuit of the peripheral circuit structure PC, the peripheral circuit lines PCL, and the peripheral contact plugs PCP. The peripheral circuit insulating layer PIL may include insulating layers stacked in multiple layers.

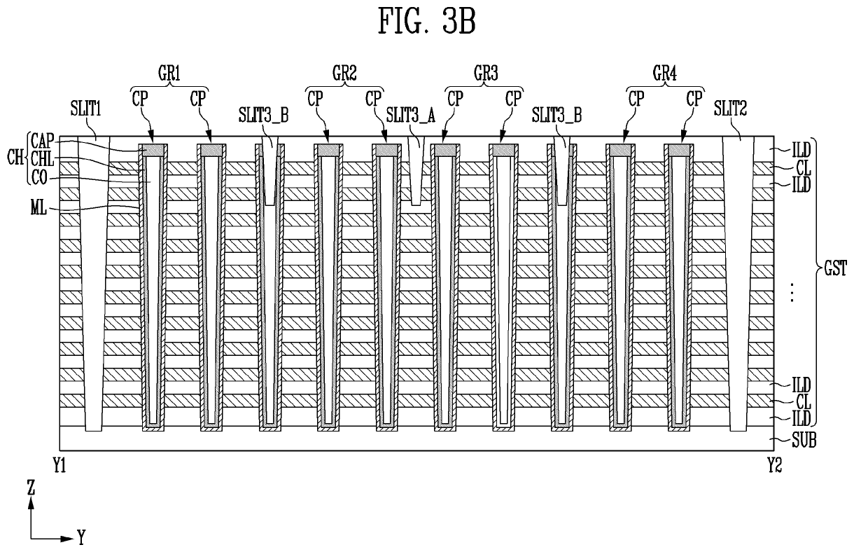

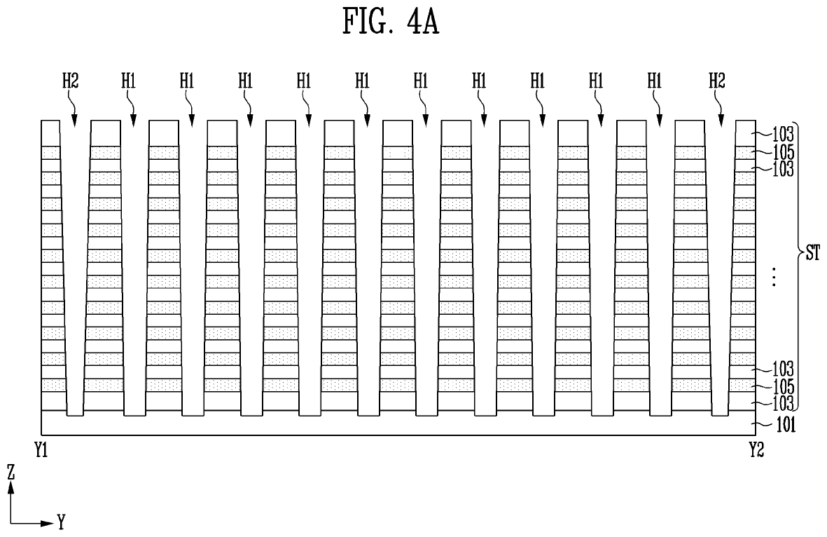

FIGS. 3A and 3B are plan and cross-sectional views illustrating a semiconductor device according to an embodiment of the present disclosure.

FIG. 3A illustrates a layout of the cell array CAR of FIG. 1, and FIG. 3B illustrates a cross-section of the cell array CAR of FIG. 1.

Referring to FIG. 3A, the cell array may include a gate stack GST, a plurality of cell plugs CP, first and second slits SLIT1 and SLIT2, and at least one or more third slits SLIT3_A and SLIT3_B.

The gate stack GST may include line patterns stacked in a vertical direction. The vertical direction may be a direction vertically crossing a first horizontal direction X and a second horizontal direction Y. The line patterns may include interlayer insulating layers and conductive patterns. A stack structure of the interlayer insulating layers and the conductive patterns is described later with reference to FIG. 3B.

The gate stack GST may be separated by the first and second slits SLIT1 and SLIT2. For example, the first and second slits SLIT1 and SLIT2 may extend in the vertical direction in the gate stack GST, may pass through the gate stack GST, and may extend in the first horizontal direction X. The first horizontal direction X may be a word line extension direction. The first and second slits SLIT1 and SLIT2 may extend in the first horizontal direction X, and may have a wave pattern or a zigzag pattern, as illustrated, along an extension direction. The first slit SLIT1 and the second slit SLIT2 may be disposed spaced apart from each other by a predetermined distance in the second horizontal direction Y and may be disposed in parallel. The second horizontal direction Y may be a direction vertically crossing the first horizontal direction X. The second horizontal direction Y may be a bit line extension direction. Because the first and second slits SLIT1 and SLIT2 extend in the first horizontal direction X and have the wave pattern or the zigzag pattern along the extension direction, and the first and second slits SLIT1 and SLIT2 may include portions extending by a predetermined length in a diagonal direction between the first horizontal direction X and the second horizontal direction Y. An angle θ between the portions extending in the diagonal direction of each of the first and second slits SLIT1 and SLIT2 may be adjusted according to a disposition position of the cell plugs CP.

Each of the first and second slits SLIT1 and SLIT2 may include an extension portion FS, which is a sidewall that extends by a predetermined length at a bent portion in which the extension direction is changed. The extension portion FS may extend in a direction parallel to the first horizontal direction X, which is an extension direction of a word line. The extension portion FS may have a flat shape, as illustrated. That is, the bent portion, in which the extension direction is changed, of each of the first and second slits SLIT1 and SLIT2 may be formed to have a sidewall parallel to the first horizontal direction X. A length D of the extension portion FS may be equal to or greater than a critical dimension of one cell plug CP. Accordingly, an outer sidewall portion of a portion where the extension direction each of the first and second slits SLIT1 and SLIT2 is changed and bent, that is, a sidewall between a portion extending in the diagonal direction and the extension portion FS may form an obtuse angle. When the outer sidewall of the portion where the extension direction of each of the first and second slits SLIT1 and SLIT2 is changed and bent has a V shape, a disposition space of the cell plug CP is reduced. Therefore, in an embodiment of the present disclosure, the portion where the extension direction of each of the first and second slits SLIT1 and SLIT2 is changed and bent may be formed to have a sidewall parallel to the first horizontal direction X, and thus the disposition space of the cell plug CP may be secured to the maximum.

The first and second slits SLIT1 and SLIT2 may be disposed at boundaries between memory blocks, respectively.

The plurality of cell plugs CP may extend in the vertical direction in the gate stack GST between the first and second slits SLIT1 and SLIT2 and may be regularly arranged. For example, the plurality of cell plugs CP may be disposed in a zigzag pattern or a matrix pattern. The plurality of cell plugs CP may be disposed by passing through the gate stack GST in the vertical direction. Each of the plurality of cell plugs CP may be formed in a cylindrical shape. Each of the plurality of cell plugs CP may include a channel structure CH extending in the vertical direction and a memory layer ML surrounding a sidewall of the channel structure CH.

The at least one or more third slits SLIT3_A and SLIT3_B may extend in the first horizontal direction X by passing through the gate stack GST between the first and second slits SLIT1 and SLIT2 by a predetermined depth. The at least one or more third slits SLIT3_A and SLIT3_B may have a wave pattern or a zigzag pattern extending in the first horizontal direction X. The at least one or more third slits SLIT3_A and SLIT3_B may overlap some cell plugs CP in a partial area. The at least one or more third slits SLIT3_A and SLIT3_B may pass through the gate stack GST by a predetermined depth, and for example, the at least one or more third slits SLIT3_A and SLIT3_B may be formed so that a conductive line for a drain select line included in the gate stack GST is separated to both ends by the at least one or more third slits SLIT3_A and SLIT3_B.

A width of the at least one or more third slits SLIT3_A and SLIT3_B may be formed to be different from a width of the first and second slits SLIT1 and SLIT2. For example, the width of the at least one or more third slits SLIT3_A and SLIT3_B may be formed to be narrower than the width of the first and second slits SLIT1 and SLIT2. The present disclosure is not limited thereto.

The first slit SLIT1 and the second slit SLIT2 may be disposed spaced apart from each other by a predetermined distance and disposed in parallel in the second horizontal direction Y. Accordingly, the number of cell plugs CP arranged in the second horizontal direction Y between the first and second slits SLIT1 and SLIT2 may be uniform.

The plurality of cell plugs CP may be divided into a plurality of groups GR1 to GR4 by the at least one or more third slits SLIT3_A and SLIT3_B. The plurality of groups GR1 to GR4 may be individually controlled by the conductive line for drain select line separated by the one or more third slits SLIT3_A and SLIT3_B. Although the plurality of groups are shown and described as four in an embodiment of the present disclosure, the present disclosure is not limited thereto, and the number of cell plugs CP included in one group is not limited.

FIG. 3B illustrates a cross section of the cell array taken along a line Y1-Y2 shown in FIG. 3A.

Referring to FIG. 3B, the semiconductor device may include the gate stack GST stacked on the substrate SUB, the plurality of cell plugs CP extending in the vertical direction Z in the gate stack GST, the first and second slits SLIT1 and SLIT2 passing through the gate stack GST in the vertical direction Z, and the at least one or more third slits SLIT3_A and SLIT3_B passing through a portion of the upper portion of the gate stack GST.

The gate stack GST may include alternately stacked interlayer insulating layers ILD and conductive lines CL. Each of the interlayer insulating layers ILD and the conductive lines CL may be a line pattern extending in the first horizontal direction X shown in FIG. 3A. A portion of the conductive lines CL may be a line for word line, and another portion may be a line for select line. For example, at least one conductive line CL disposed at the lowermost end of the conductive lines CL may be the line for source select line, at least one conductive line CL disposed at the uppermost end among the conductive lines CL may be a line for drain select line, and conductive lines CL disposed between the line for source select line and the line for drain select line may be the line for word line.

The conductive lines CL may include a conductive material such as polysilicon, tungsten, molybdenum, or metal. The interlayer insulating layers ILD may for insulating the stacked conductive lines CL from each other. The interlayer insulating layers ILD may include an insulating material such as oxide, nitride, or an air gap. Among the interlayer insulating layers ILD, the interlayer insulating layer ILD disposed at the uppermost portion may be formed thicker than remaining interlayer insulating layers ILD.

The first slit SLIT1 and the second slit SLIT2 may be disposed inside the gate stack GST. The first slit SLIT1 and the second slit SLIT2 may pass through the gate stack GST in the vertical direction Z to separate adjacent gate stacks GST from each other. The first slit SLIT1 and the second slit SLIT2 may be formed of an insulating material.

The plurality of cell plugs CP may be disposed in the gate stack GST between the first and second slits SLIT1 and SLIT2. The plurality of cell plugs CP may extend in the vertical direction Z. Each of the plurality of cell plugs CP may include the channel structure CH extending in the vertical direction Z and the memory layer ML surrounding the sidewall of the channel structure CH.

The channel structure CH may include a channel layer CHL extending in the vertical direction Z, and may further include a core insulating layer CO extending in the vertical direction Z inside the channel layer CHL and a capping layer CAP disposed on the core insulating layer CO.

The channel layer CHL may include a semiconductor layer. As an example, the channel layer CHL may include silicon. The core insulating layer CO may include an insulating layer. The capping layer CAP may be a silicon layer into which an impurity is injected.

The memory layer ML may include a tunnel insulating layer, a data storage layer, and a blocking insulating layer. The tunnel insulating layer may extend in the vertical direction Z while surrounding the channel layer CHL. The tunnel insulating layer may be formed of a silicon oxide layer capable of charge tunneling. The data storage layer may extend in the vertical direction Z while surrounding the tunnel insulating layer. The data storage layer may be formed of a material layer capable of storing changed data using Fowler-Nordheim tunneling. As an embodiment, the data storage layer may be formed of a charge trap nitride layer. The blocking insulating layer may extend in the vertical direction Z while surrounding the data storage layer. The blocking insulating layer may include an oxide layer capable of blocking a charge.

The at least one or more third slits SLIT3_A and SLIT3_B may pass through the gate stack GST between the first and second slits SLIT1 and SLIT2 by a predetermined depth. The at least one or more third slits SLIT3_A and SLIT3_B may overlap the cell plugs CP in a partial area. The at least one or more third slits SLIT3_A and SLIT3_B may pass through the gate stack GST by a predetermined depth, and for example, the at least one or more third slits SLIT3_A and SLIT3_B may be formed so that a conductive line for drain select line included in the gate stack GST is separated into both ends by the at least one or more third slits SLIT3_A and SLIT3_B. The at least one or more third slits SLIT3_A and SLIT3_B may be formed of an insulating material.

The plurality of cell plugs CP may be divided into the plurality of groups GR1 to GR4 by the at least one or more third slits SLIT3_A and SLIT3_B.

As described above, as the first and second slits SLIT1 and SLIT2 are disposed to extend in the first horizontal direction X, which is the extension direction of the word line, and have the zigzag pattern or the wave pattern, tensile stress or compressive stress generated in one direction of the memory block, for example, the first horizontal direction X, may be distributed in the second horizontal direction Y.

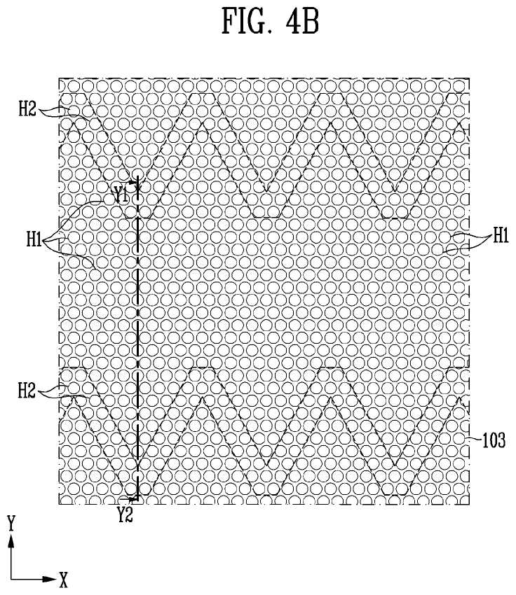

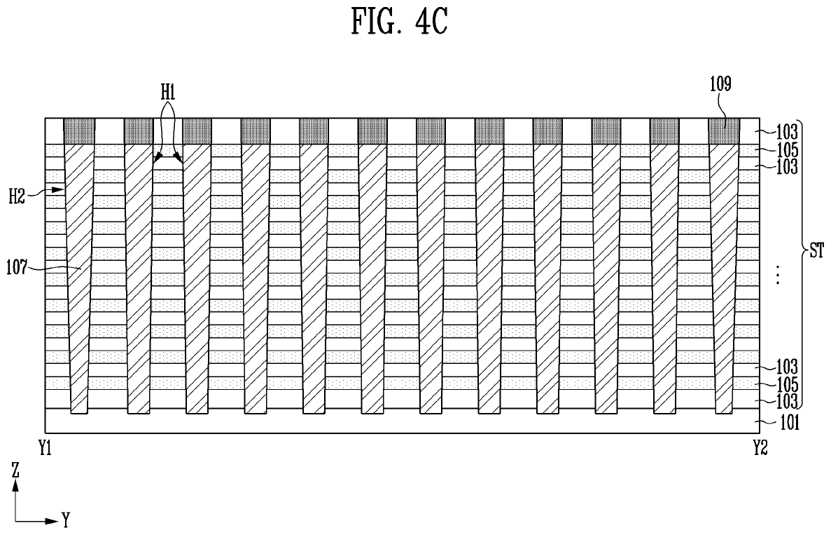

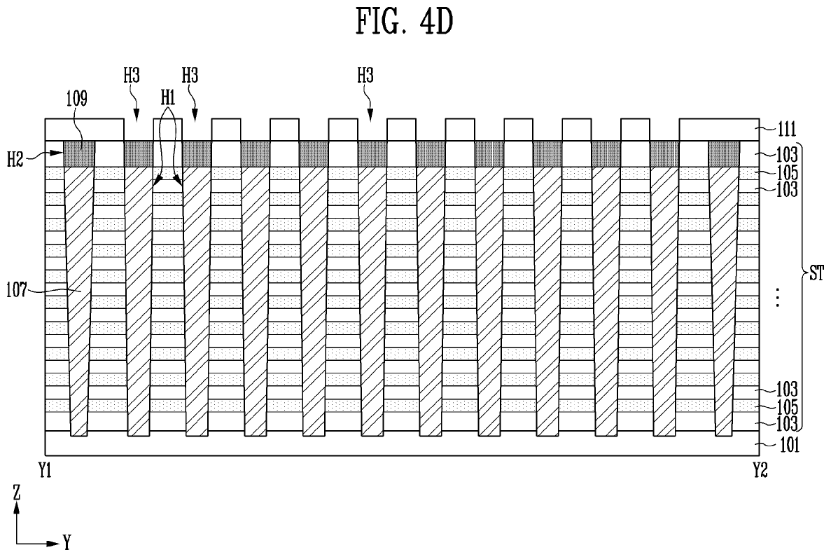

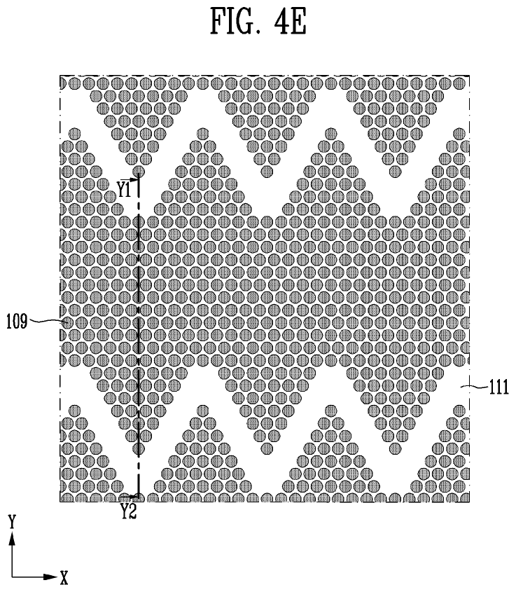

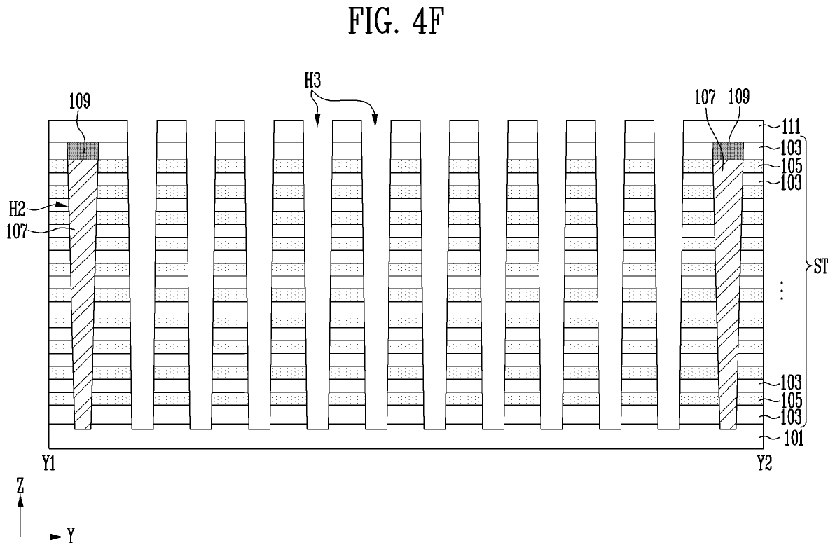

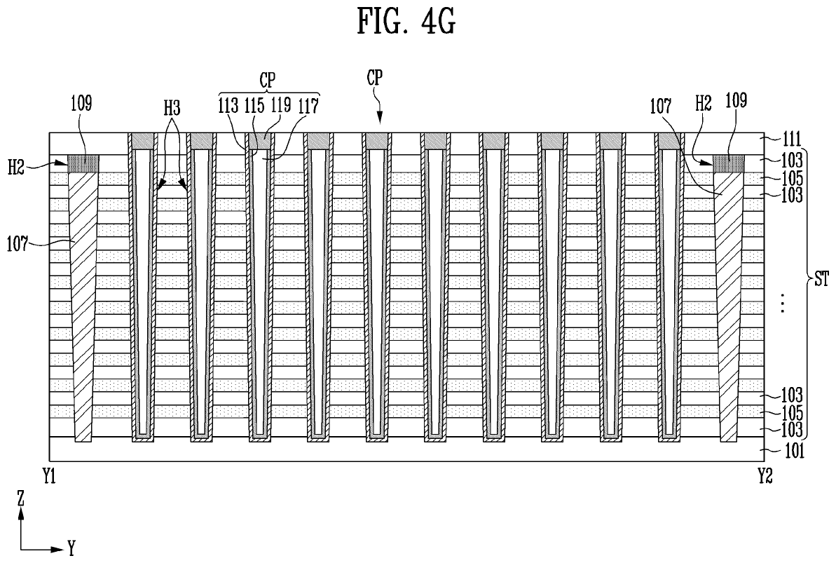

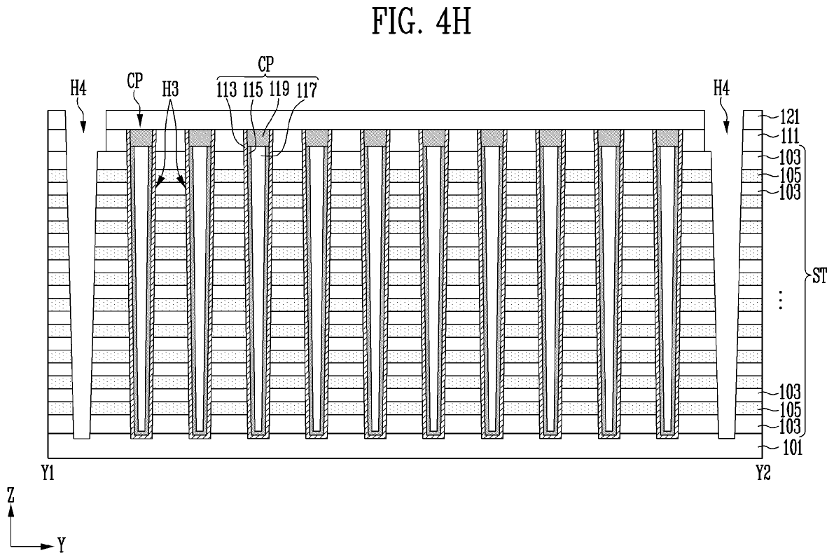

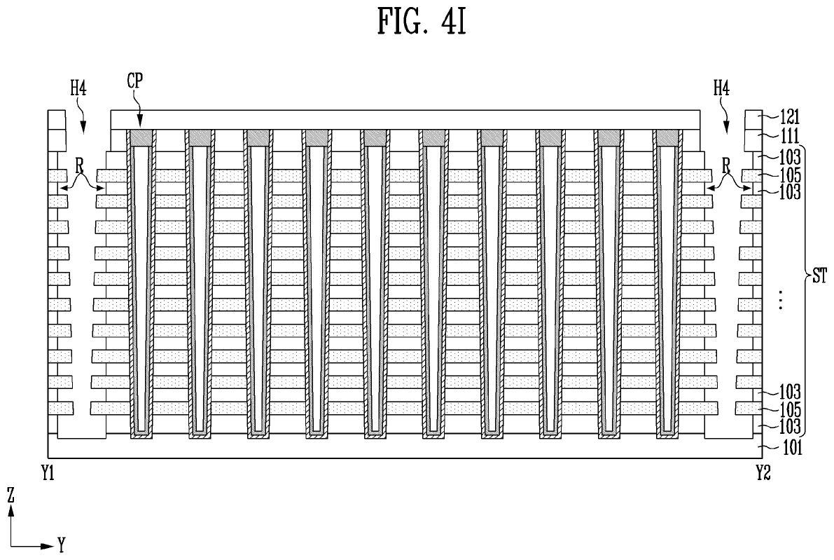

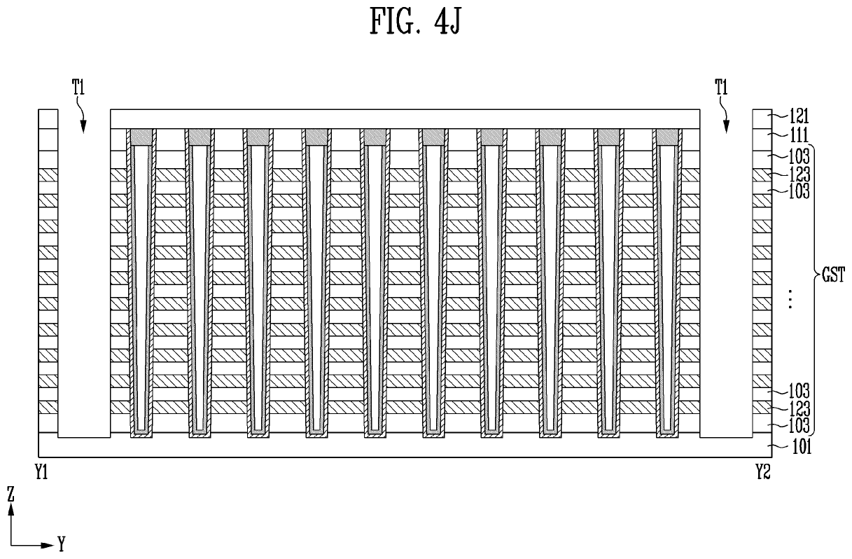

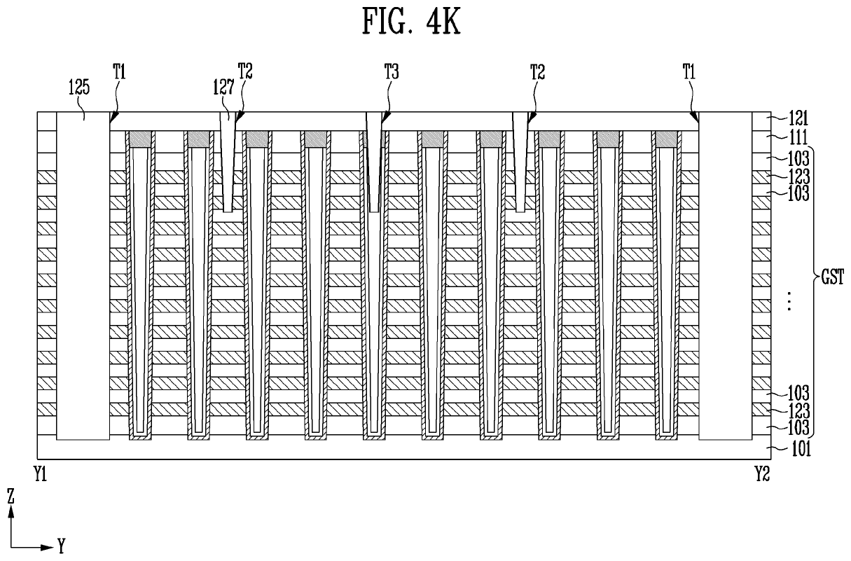

FIGS. 4A to 4K are plan views and cross-sectional views illustrating a method of manufacturing a semiconductor device according to the present disclosure.

Referring to FIG. 4A, a stack ST in which interlayer insulating layers 103 and sacrificial layers 105 are alternately stacked may be formed. The stack ST may be formed on a substrate 101 including a peripheral circuit (not shown).

The sacrificial layers 105 may be formed of a material different from that of the interlayer insulating layers 103. For example, the interlayer insulating layers 103 may be formed of an oxide such as a silicon oxide layer. The sacrificial layers 105 may be formed of a material having an etching rate different from that of the interlayer insulating layers 103. For example, the sacrificial layers 105 may be formed of a nitride such as a silicon nitride layer.

The interlayer insulating layer 103 disposed at the lowermost portion and the interlayer insulating layer 103 disposed at the uppermost portion may be formed to be thicker than remaining interlayer insulating layers 103.

Thereafter, a mask pattern (not shown) of which a portion is open among an area where the cell plugs are to be formed and an area where the first and second slits are to be formed is formed on the stack ST, and an etching process using the mask pattern is performed, to form a plurality of preliminary channel holes H1 and a plurality of preliminary slit holes H2 passing through the stack ST. A diameter of the plurality of preliminary slit holes H2 may be equal to or greater than a diameter of the plurality of preliminary channel holes H1.

FIG. 4B is a plan view of a semiconductor device on which a processing step related to FIG. 4A described above is performed. Referring to FIG. 4B, the plurality of preliminary channel holes H1 and the plurality of preliminary slit holes H2 may be spaced apart from each other and regularly arranged. For example, the plurality of preliminary channel holes H1 and the plurality of preliminary slit holes H2 may be arranged in a zigzag pattern.

The area where the first and second slits are to be formed may have a zigzag pattern. Accordingly, the plurality of preliminary slit holes H2 may also be formed in the area where the first and second slits are to be formed and may be arranged in a zigzag pattern. As another embodiment, the plurality of preliminary channel holes H1 and the plurality of preliminary slit holes H2 may be arranged in a matrix pattern.

Referring to FIG. 4C, a gap fill pattern 107 is formed by filling the plurality of preliminary channel holes H1 and the plurality of preliminary slit holes H2 with a gap fill material. The gap fill pattern 107 may include carbon.

Thereafter, after a portion of an upper end of the gap fill pattern 107 is etched, an auxiliary pattern 109 may be formed in a portion where the gap fill pattern 107 is etched and removed. That is, the gap fill pattern 107 may be formed at a lower end and a middle portion of each of the plurality of preliminary channel holes H1 and the plurality of preliminary slit holes H2, and the auxiliary pattern 109 that is in contact with the gap fill pattern 107 may be formed at an upper end of each of the plurality of preliminary channel holes H1 and the plurality of preliminary slit holes H2. The auxiliary pattern 109 may include a tungsten pattern and may further include a titanium nitride layer surrounding a surface of the tungsten pattern.

As another embodiment, each of the plurality of preliminary channel holes H1 and the plurality of preliminary slit holes H2 may be filled with only the gap fill pattern 107 without forming the auxiliary pattern 109.

Referring to FIGS. 4D and 4E, after forming a first insulating layer 111 on the stack ST, the first insulating layer 111 is selectively etched to form channel holes H3 through which the auxiliary patterns 109 formed in the plurality of preliminary channel holes H1 is exposed. At this time, the auxiliary pattern 109 formed in the plurality of preliminary slit holes H2 is not exposed by the first insulating layer 111.

Referring to FIG. 4F, an etching process is performed to remove the auxiliary pattern 109 exposed through the channel holes H3 and the gap fill pattern inside the plurality of preliminary channel holes H1. Accordingly, the channel holes H3 may extend in the vertical direction Z so that the substrate 101 is exposed.

At this time, the auxiliary pattern 109 and the gap fill pattern 107 formed in the plurality of preliminary slit holes H2 are protected by the first insulating layer 111 and are not removed.

Referring to FIG. 4G, the cell plug CP is formed inside each of the channel holes H3.

For example, the memory layer 113 is formed by sequentially forming a blocking insulating layer, a data storage layer, and a tunnel insulating layer on a sidewall of each of the channel holes H3. The blocking insulating layer may be formed on the sidewall of each of the channel holes H3. The blocking insulating layer may include an oxide layer capable of blocking a charge. As an embodiment, the blocking insulating layer may be formed of aluminum oxide Al₂O₃. The data storage layer may be formed on a sidewall of the blocking insulating layer. The data storage layer may be formed of a charge trap layer, a material layer including a conductive nano dot, or a phase change material layer. For example, the data storage layer may store changed data using Fowler-Nordheim tunneling. To this end, the data storage layer may be formed of a silicon nitride layer capable of trapping a charge. The tunnel insulating layer may be formed on a sidewall of the data storage layer. The tunnel insulating layer may be formed of a silicon oxide layer capable of charge tunneling.

Thereafter, a channel layer 115 is formed on a sidewall of the memory layer 113. As an embodiment, the channel layer 115 may include silicon. Thereafter, a core insulating layer 117 may be formed by filling a central area of each of the channel holes H3 with an insulating material.

Thereafter, an upper portion of the channel layer 115 and the core insulating layer 117 may be etched by a predetermined thickness, and a capping layer 119 may be formed in a space where the channel layer 115 and the core insulating layer 117 are removed. The capping layer 119 may be formed of a doped semiconductor layer.

Referring to FIG. 4H, a second insulating layer 121 is formed on the first insulating layer 111 and the cell plugs CP. The second insulating layer 121 may include oxide.

Thereafter, the second insulating layer 121 is selectively etched to form slit holes H4 exposing the auxiliary pattern 109 of FIG. 4G formed in the plurality of preliminary slit holes H2 of FIG. 4G. At this time, the cell plugs CP are not exposed by the second insulating layer 121.

Thereafter, the exposed auxiliary pattern and the gap fill pattern 107 of FIG. 4G may be removed to extend the slit holes H4 downwardly.

Referring to FIG. 4O, an additional etching process is performed to etch a sidewall of the stack 103 exposed through the slit holes H4 by a predetermined thickness to form a recess area R. Therefore, the slit holes H4 adjacent to each other may be connected to each other by the recess area R.

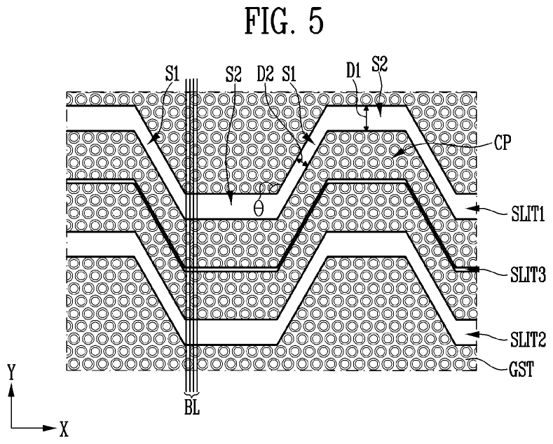

Referring to FIG. 4J, the sacrificial layers 105 of FIG. 4I exposed through the slit holes H4 of FIG. 4I may be removed. By removing the sacrificial layers 105 of FIG. 4I, the slit holes H4 of FIG. 4I adjacent to each other may be connected to each other, and thus a trench T1 passing through the stack ST of FIG. 4I and exposing the substrate 101 is formed in the area where the first and second slits are formed. Similarly to the first and second slits SLIT1 and SLIT2 of FIG. 3B, the trench T1 may have a zigzag pattern or a wave pattern and may extend in the first horizontal direction X. As another embodiment, the trench T1 may have a zigzag pattern or a wave pattern similarly to the first and second slits SLIT1 and SLIT2 of FIG. 5 described later, and may include a portion extending in a line shape in the first horizontal direction X.

Thereafter, a plurality of conductive patterns 123 are formed by filling a space from which the sacrificial layers 105 of FIG. 4I are removed with a conductive material. For example, the plurality of conductive patterns 123 may be formed by including a conductive material such as polysilicon doped with an N-type impurity, tungsten, tungsten silicide, molybdenum, or metal.

The plurality of interlayer insulating layers 103, the plurality of conductive patterns 123, the first insulating layer 111, and the second insulating layer 121 may be defined as the gate stack GST.

Thereafter, the conductive material inside the trench T1 may be removed so that the plurality of conductive patterns 123 are separated from each other by the trench T1.

Referring to FIG. 4K, first and second slits 125 are formed by filling the trench T1 with an insulating material. The first and second slits 125 may include oxide.

The first and second slits 125 may extend in the first horizontal direction X in a zigzag pattern or a wave pattern similarly to the first and second slits SLIT1 and SLIT2 of FIG. 3B. As another embodiment, the first and second slits 125 may have a zigzag pattern or a wave pattern similarly to the first and second slits SLIT1 and SLIT2 of FIG. 5 described later, and may include a portion extending in a straight line in the first horizontal direction X in one portion.

Thereafter, an etching process is performed to form a second trench T2 and a third trench T3 passing through an upper portion of the gate stack GST by a predetermined thickness. The second trench T2 and the third trench T3 may be formed to pass through at least one conductive pattern 123 used as a drain select line among the plurality of conductive patterns 123. The second trench T2 and the third trench T3 may be formed to overlap a portion of the cell plug CP.

Thereafter, third slits 127 are formed by filling the second trench T2 and the third trench T3 with an insulating material. The third slits 127 may extend in the first horizontal direction X in a zigzag pattern or a wave pattern similarly to the third slits SLIT3_A and SLIT3_B of FIG. 3B.

FIG. 5 is a plan view illustrating a semiconductor device according to another embodiment of the present disclosure.

Referring to FIG. 5, the cell array may include the gate stack GST, the plurality of cell plugs CP, the first and second slits SLIT1 and SLIT2, and at least one third slit SLIT3.

The gate stack GST may include line patterns stacked in the vertical direction. The vertical direction may be a direction vertically crossing the first horizontal direction X and the second horizontal direction Y. The line patterns may include interlayer insulating layers and conductive patterns. A stack structure of the interlayer insulating layers and the conductive patterns may be the same as that of the gate stack structure GST described above with reference to FIG. 3B.

The gate stack GST may be separated by the first and second slits SLIT1 and SLIT2. For example, the first and second slits SLIT1 and SLIT2 may extend in the vertical direction in the gate stack GST, may pass through the gate stack GST, and may extend in the first horizontal direction X. The first horizontal direction X may be the word line extension direction. The second horizontal direction Y may be a direction vertically crossing the first horizontal direction X. The second horizontal direction Y may be an extension direction of a bit line BL. The first and second slits SLIT1 and SLIT2 may be disposed at boundaries between memory blocks, respectively.

The first and second slits SLIT1 and SLIT2 may extend in the first horizontal direction X and may have a wave pattern or a zigzag pattern along an extension direction.

For example, each of the first and second slits SLIT1 and SLIT2 may include first portions S1 extending in a diagonal direction between the first horizontal direction X and the second horizontal direction Y and having a mirror symmetrical structure with respect to the second horizontal direction Y, and second portions S2 connecting between the first portions S1 and extending in the first horizontal direction X. For example, one first portion S1 extends in the diagonal direction between the first horizontal direction X and the second horizontal direction Y, and one end of one first portion S1 is connected to one end of the second portion S2 extending in the first horizontal direction X. One end of another first portion S1 is connected to another end of the second portion S2. That is, each of the first and second slits SLIT1 and SLIT2 includes a portion extending in the diagonal direction between the first horizontal direction X and the second horizontal direction Y and a portion extending in the first horizontal direction X. An extension length of the second portion S2 may be longer than an arrangement length of at least three cell plugs CP.

A thickness D2 of the first portion S1 of each of the first and second slits SLIT1 and SLIT2 may be equal to or less than a thickness D1 of the second portion S2.

The first slit SLIT1 and the second slit SLIT2 may be disposed spaced apart from each other by a predetermined distance and disposed in parallel in the second horizontal direction Y. Accordingly, the number of cell plugs arranged in the second horizontal direction Y between the first and second slits SLIT1 and SLIT2 may be uniform.

The second horizontal direction Y may be a direction vertically crossing the first horizontal direction X. The second horizontal direction Y may be an extension direction of the bit line BL. The first and second slits SLIT1 and SLIT2 may be disposed at boundaries between memory blocks, respectively.

The plurality of cell plugs CP may extend in the vertical direction in the gate stack GST between the first and second slits SLIT1 and SLIT2 and may be regularly arranged. For example, the plurality of cell plugs CP may be disposed in a zigzag pattern or a matrix pattern. The plurality of cell plugs CP may be disposed by passing through the gate stack GST in the vertical direction. Each of the plurality of cell plugs CP may be formed in a cylindrical shape. Each of the plurality of cell plugs CP may include the channel structure CH extending in the vertical direction and the memory layer ML surrounding the sidewall of the channel structure CH.

In each of the first and second slits SLIT1 and SLIT2, an angle θ of a portion contacting the first portion S1 and the second portion S2 may be adjusted according to a disposition position of the cell plugs CP. For example, when the cell plugs CP are arranged in a matrix pattern, the angle θ may be 90°, and when the cell plugs CP are arranged in a zigzag pattern, the angle θ may have an obtuse angle greater than 90°.

The at least one third slit SLIT3 may extend in the first horizontal direction X by passing through the gate stack GST between the first and second slits SLIT1 and SLIT2 by a predetermined depth. The at least one third slit SLIT3 may have a wave pattern or a zigzag pattern extending in the first horizontal direction X. The at least one third slit SLIT3 may overlap some cell plugs CP in a partial area. The at least one third slit SLIT3 may pass through the gate stack GST by a predetermined depth, and for example, the at least one third slit SLIT3 may be formed so that a conductive line for a drain select line included in the gate stack GST is separated to both ends by the at least one third slit SLIT3. The at least one third slit SLIT3 may be disposed parallel to the first and second slits SLIT1 and SLIT2 in the first and second slits SLIT1 and SLIT2.

A width of the at least one third slit SLIT3 may be formed to be different from the width of the first and second slits SLIT1 and SLIT2.

The semiconductor device according to another embodiment of the present disclosure described above may be manufactured according to the method of manufacturing the semiconductor device described with reference to FIGS. 4A to 4K. In this case, in FIG. 4B, the plurality of preliminary slit holes H2 may be formed to include a portion extending in the diagonal direction between the first horizontal direction X and the second horizontal direction Y and a portion extending by a predetermined length in the first horizontal direction X.

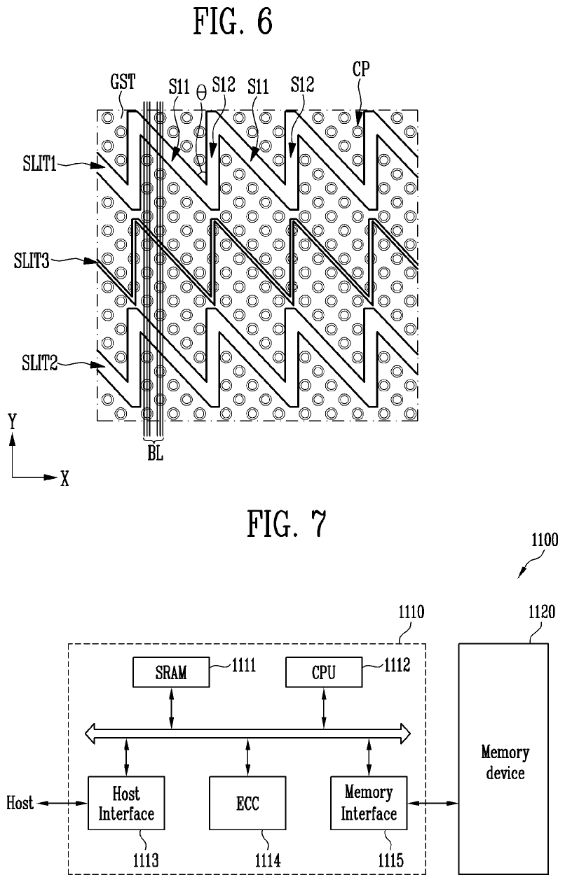

FIG. 6 is a plan view illustrating a semiconductor device according to still another embodiment of the present disclosure.

Referring to FIG. 6, the cell array may include the gate stack GST, the plurality of cell plugs CP, the first and second slits SLIT1 and SLIT2, and the at least one third slit SLIT3.

The gate stack GST may include line patterns stacked in the vertical direction. The vertical direction may be a direction vertically crossing the first horizontal direction X and the second horizontal direction Y. The line patterns may include interlayer insulating layers and conductive patterns. A stack structure of the interlayer insulating layers and the conductive patterns may be the same as that of the gate stack structure GST described above with reference to FIG. 3B.

The gate stack GST may be separated by the first and second slits SLIT1 and SLIT2. For example, the first and second slits SLIT1 and SLIT2 may extend in the vertical direction in the gate stack GST, may pass through the gate stack GST, and may extend in the first horizontal direction X. The first horizontal direction X may be the word line extension direction. The second horizontal direction Y may be a direction vertically crossing the first horizontal direction X. The second horizontal direction Y may be an extension direction of a bit line BL. The first and second slits SLIT1 and SLIT2 may be disposed at boundaries between memory blocks, respectively.

The first and second slits SLIT1 and SLIT2 may extend in the first horizontal direction X and may have a wave pattern or a zigzag pattern along an extension direction.

For example, each of the first and second slits SLIT1 and SLIT2 may include first portions S11 extending by a predetermined length in the diagonal direction between the first horizontal direction X and the second horizontal direction Y, and second portions S12 connecting between the first portions S11 and extending in the second horizontal direction Y. For example, one first portion S11 extends in the diagonal direction between the first horizontal direction X and the second horizontal direction Y, one end of one second portion S12 extending in the second horizontal direction Y is connected to an end of any one first portion S11, and another end of the second portion S12 is connected to an end of the another first portion S11. That is, each of the first and second slits SLIT1 and SLIT2 includes a portion extending in the diagonal direction between the first horizontal direction X and the second horizontal direction Y and a portion extending in the second horizontal direction Y.

The first portions S11 of each of the first and second slits SLIT1 and SLIT2 may be disposed spaced apart from each other by a predetermined distance and disposed in parallel in the second horizontal direction Y. Accordingly, the number of cell plugs arranged in the second horizontal direction Y between the first and second slits SLIT1 and SLIT2 may be uniform.

The second horizontal direction Y may be a direction vertically crossing the first horizontal direction X. The second horizontal direction Y may be an extension direction of the bit line BL. The first and second slits SLIT1 and SLIT2 may be disposed at boundaries between memory blocks, respectively.

The plurality of cell plugs CP may extend in the vertical direction in the gate stack GST between the first and second slits SLIT1 and SLIT2 and may be regularly arranged. For example, the plurality of cell plugs CP may be disposed in a zigzag pattern or a matrix pattern. The plurality of cell plugs CP may be disposed by passing through the gate stack GST in the vertical direction. Each of the plurality of cell plugs CP may be formed in a cylindrical shape. Each of the plurality of cell plugs CP may include the channel structure CH extending in the vertical direction and the memory layer ML surrounding the sidewall of the channel structure CH.

In each of the first and second slits SLIT1 and SLIT2, an angle θ of a portion contacting the first portion S11 and the second portion S12 may be adjusted according to a disposition position of the cell plugs CP. For example, the angle θ of the portion contacting the first portion S11 and the second portion S12 may have an acute angle less than 90°.

The at least one third slit SLIT3 may extend in the first horizontal direction X by passing through the gate stack GST between the first and second slits SLIT1 and SLIT2 by a predetermined depth. The at least one third slit SLIT3 may have a wave pattern or a zigzag pattern extending in the first horizontal direction X. The at least one third slit SLIT3 may overlap some cell plugs CP in a partial area. The at least one third slit SLIT3 may pass through the gate stack GST by a predetermined depth, and for example, the at least one third slit SLIT3 may be formed so that a conductive line for a drain select line included in the gate stack GST is separated to both ends by the at least one third slit SLIT3. The at least one third slit SLIT3 may be disposed parallel to the first and second slits SLIT1 and SLIT2 in the first and second slits SLIT1 and SLIT2.

The semiconductor device according to still another embodiment of the present disclosure described above may be manufactured according to the method of manufacturing the semiconductor device described with reference to FIGS. 4A to 4K. In this case, in FIG. 4B, the plurality of preliminary slit holes H2 may be formed to include a portion extending in the diagonal direction between the first horizontal direction X and the second horizontal direction Y and a portion extending by a predetermined length in the second horizontal direction Y.

FIG. 7 is a block diagram illustrating a configuration of a memory system according to an embodiment of the present disclosure.

Referring to FIG. 7, the memory system 1100 according to an embodiment of the present disclosure includes a memory device 1120 and a memory controller 1110.

The memory device 1120 may be a multi-chip package configured of a plurality of flash memory chips.

The memory controller 1110 may be configured to control the memory device 1120, and may include static random-access memory (SRAM) 1111, a CPU 1112, a host interface 1113, an error correction code (ECC) 1114, and a memory interface 1115. The SRAM 1111 is used as operation memory of the CPU 1112, the CPU 1112 performs an overall control operation for data exchange of the memory controller 1110, and the host interface 1113 includes a data exchange protocol of a host connected to the memory system 1100. The ECC 1114 detects and corrects errors included in data read from the memory device 1120. The memory interface 1115 performs interfacing with the memory device 1120. In addition, the memory controller 1110 may further include read-only memory (ROM) or the like that stores code data for interfacing with the host.

The above-described memory system 1100 may be a memory card or a solid-state disk (SSD) in which the memory device 1120 and the memory controller 1110 are combined. For example, when the memory system 1100 is the SSD, the memory controller 1110 may communicate with the outside (for example, the host) through one of various interface protocols such as a universal serial bus (USB), a multimedia card (MMC), a peripheral component interconnection-express (PCI-E), a serial advanced technology attachment (SATA), a parallel advanced technology attachment (PATA), a small computer system interface (SCSI), an enhanced small disk interface (ESDI), and integrated drive electronics (IDE).

What is claimed is:

1. A semiconductor device comprising:
a gate stack including a plurality of conductive lines extending in a first horizontal direction;
a first slit and a second slit passing through the gate stack in a vertical direction and extending in the first horizontal direction; and
a plurality of cell plugs extending in the vertical direction orthogonal to the first horizontal direction in the gate stack between the first slit and the second slit,
wherein each of the first slit and the second slit includes a first portion extending in a diagonal direction between the first horizontal direction and a second horizontal direction orthogonal to the first horizontal direction, and a second portion extending in the first horizontal direction.

2. The semiconductor device of claim 1, wherein the second horizontal direction is a bit line extension direction in which bit lines extend.

3. The semiconductor device of claim 1, wherein the first horizontal direction is a word line extension direction in which word lines extend.

4. The semiconductor device of claim 1, wherein an angle between the first portion and the second portion is equal to or greater than 90 degrees.

5. The semiconductor device of claim 1, wherein the first slit and the second slit are spaced apart from each other in the second horizontal direction, and
the number of the plurality of cell plugs arranged in the second horizontal direction between the first slit and the second slit is uniform.

6. The semiconductor device of claim 1, wherein a thickness of the first portion and a thickness of the second portion are different from or equal to each other.

7. The semiconductor device of claim 1, further comprising:
at least one third slit extending in the first horizontal direction and passing through an upper portion of the gate stack by a predetermined thickness between the first slit and the second slit.

8. The semiconductor device of claim 1, wherein the plurality of cell plugs are arranged in a zigzag pattern or a matrix pattern.

9. A semiconductor device comprising:
a gate stack including a plurality of conductive lines extending in a first horizontal direction;
a first slit and a second slit disposed at both ends of the gate stack and extending parallel to the first horizontal direction;
a plurality of cell plugs extending in a vertical direction orthogonal to the first horizontal direction in the gate stack between the first slit and the second slit; and
at least one third slit extending in the first horizontal direction by passing through an upper portion of the gate stack between the first slit and the second slit by a predetermined thickness, and extending in parallel with the first slit and the second slit,
wherein the first slit and the second slit have a wave pattern or a zigzag pattern along the first horizontal direction.

10. The semiconductor device of claim 9, wherein each of the first slit and the second slit includes a first portion extending in a diagonal direction between the first horizontal direction and a second horizontal direction orthogonal to the first horizontal direction, and a second portion extending in the first horizontal direction.

11. The semiconductor device of claim 10, wherein the first horizontal direction is a word line extension direction in which word lines extend, and the second horizontal direction is a bit line extension direction in which bit lines extend.

12. The semiconductor device of claim 10, wherein an angle between the first portion and the second portion is equal to or greater than 90 degrees.

13. The semiconductor device of claim 9, wherein the plurality of cell plugs are arranged in a zigzag pattern or a matrix pattern.

14. A method of manufacturing a semiconductor device, the method comprising:
forming a plurality of preliminary channel holes and a plurality of preliminary slit holes passing through a stack in which a plurality of interlayer insulating layers and a plurality of sacrificial layers are alternately stacked;
filling the plurality of preliminary channel holes and the plurality of preliminary slit holes with a gap fill pattern;
forming a first insulating layer on the stack, and forming channel holes exposing the gap fill patterns formed inside the plurality of preliminary channel holes, by selectively etching the first insulating layer;
extending the channel holes into the stack by removing the gap fill patterns exposed through the channel holes;
forming cell plugs inside the channel holes;
forming a second insulating layer on the cell plugs and the first insulating layer, and forming slit holes exposing the gap fill patterns formed inside the plurality of preliminary slit holes, by selectively etching the second insulating layer and the first insulating layer;
forming a recess area by removing the gap fill patterns exposed through the slit holes and etching the plurality of interlayer insulating layers exposed through a sidewall of the slit holes by a predetermined thickness, the recess area of adjacent slit holes being in contact with each other to be connected each other;
forming a plurality of conductive layers in a space where the plurality of sacrificial layers are removed, after removing the plurality of sacrificial layers exposed through the slit holes;
forming a trench in which the slit holes are connected to each other by removing the plurality of conductive layers remaining inside the slit holes; and
forming a slit by filling the trench with an insulating material.

15. The method of claim 14, wherein forming the plurality of preliminary channel holes and the plurality of preliminary slit holes comprises forming the plurality of preliminary slit holes to be arranged in a zigzag pattern or a wave pattern.

16. The method of claim 14, wherein the gap fill pattern includes carbon.

17. The method of claim 14, further comprising:
forming an auxiliary pattern in an area where the gap fill pattern is etched after etching an upper end of the gap fill pattern by a predetermined thickness, before forming the first insulating layer.

18. The method of claim 17, wherein the auxiliary pattern further includes a tungsten pattern and a titanium nitride layer surrounding a surface of the tungsten pattern.

19. The method of claim 14, wherein the trench extends in a word line direction in which word lines extend and has a wave pattern or a zigzag pattern along the extension direction.

20. The method of claim 14, further comprising:
forming an additional slit passing through the second insulating layer, the first insulating layer, and at least one conductive layer disposed on an uppermost portion of the plurality of conductive layers.
